(19) United States
(12) Patent Application Publication
(10) Pub. No.: US 2025/0212428 A1
(43) Pub. Date: Jun. 26, 2025

(54) SEMICONDUCTOR DEVICE

(71) Applicant: Renesas Electronics Corporation, Tokyo (JP)

(72) Inventors: Tomohiro IMAI, Tokyo (JP); Atsushi SAKAI, Tokyo (JP); Zen INOUE, Tokyo (JP); Yudai HIGA, Tokyo (JP)

(21) Appl. No.: 18/950,432

(22) Filed: Nov. 18, 2024

(30) Foreign Application Priority Data
Dec. 20, 2023 (JP) 2023-214798

(51) Int. Cl. H01L 29/872; H01L 29/06

(52) U.S. Cl. CPC H10D 8/60; H10D 62/107

(57) ABSTRACT

A semiconductor device includes a semiconductor substrate, a first semiconductor region formed in the semiconductor substrate, a second semiconductor region surrounding the first semiconductor region in plan view, a first conductive layer formed on the first semiconductor region, a first electrode formed on the first conductive layer, a cathode region connected to the first electrode via the first conductive layer, a second conductive layer in contact with the first semiconductor region, a second electrode formed on the second conductive layer, and a first region disposed between a region in contact with the first conductive layer of the first semiconductor region and the cathode region in a direction along the upper surface of the semiconductor substrate, and the first region is in contact with a lower surface of the second conductive layer. A depth of the first region is greater than a depth of the cathode region.

### CROSS-REFERENCE TO RELATED APPLICATIONS

The disclosure of Japanese Patent Application No. 2023-214798 filed on Dec. 20, 2023, including the specification, drawings and abstract is incorporated herein by reference in its entirety.

### BACKGROUND

The present disclosure is related to a semiconductor device, particularly to a semiconductor device including a Schottky barrier diode.

A Schottky Barrier Diode (SBD) is a rectifying element that utilizes the Schottky barrier formed by the junction of metal and semiconductor. Compared to diodes that utilize a PN junction, Schottky barrier diodes have lower forward voltage characteristics and faster switching speeds. However, there is a problem that the leakage current of Schottky barrier diodes is larger than that of diodes utilizing PN junctions.

There are disclosed techniques listed below.
[Patent Document 1] Japanese Unexamined Patent Application Publication No. 2006-310555

Patent Document 1 discloses an SBD that: includes a semiconductor region of a first conductivity type, an anode electrode, a guard ring of a second conductivity type formed along the periphery of the anode electrode, an isolation insulating film that isolates the anode electrode around the guard ring, and a mask for the anode electrode. With such a configuration, it is possible to reduce the reverse leakage current of the SBD.

### SUMMARY

In the reverse bias state of a Schottky barrier diode, not only can the electric field concentrate at the corners of the Schottky electrode, but it can also reach directly under the Schottky electrode. Such generation of an electric field can cause leakage current due to tunneling.

Other problems and novel features will become apparent from the description of this specification and the accompanying drawings.

In this disclosure, a semiconductor device includes a semiconductor substrate having an upper surface, a first semiconductor region formed in the semiconductor substrate, a second semiconductor region formed in the semiconductor substrate and surrounding the first semiconductor region in plan view, a first conductive layer formed on the first semiconductor region, a first electrode formed on the first conductive layer, a cathode region formed in the first semiconductor region and connected to the first electrode via the first conductive layer, a second conductive layer formed on the first semiconductor region and in contact with the first semiconductor region, a second electrode formed on the second conductive layer, and a first region formed in the first semiconductor region and disposed between a region in contact with the second conductive layer of the first semiconductor region and the cathode region, in a direction along the upper surface of the semiconductor substrate, and the region is in contact with a lower surface of the second conductive layer. When the upper surface of the semiconductor substrate is used as a reference surface, a depth of the first region is greater than a depth of the cathode region. The semiconductor substrate, the second semiconductor region, and the first region each have a first conductivity type. The first semiconductor region and the cathode region each have a second conductivity type opposite the first conductivity type.

This disclosure can provide a semiconductor device that can further suppress leakage current.

### BRIEF DESCRIPTION OF THE DRAWINGS

FIG. 1 is a cross-sectional view of a semiconductor device of a first embodiment.

FIG. 2 is a cross-sectional view of the semiconductor device of the first embodiment.

FIG. 3A is a cross-sectional view of the semiconductor device of the first embodiment.

FIG. 3B is a cross-sectional view of the semiconductor device of the first embodiment.

FIG. 4A is a diagram showing the potential distribution of the semiconductor device of the first embodiment.

FIG. 4B is a diagram showing the potential distribution of the semiconductor device of the first embodiment.

FIG. 4C is a diagram showing the potential distribution of the semiconductor device of the first embodiment.

FIG. 5 is a diagram showing the driving voltage and leakage current of the semiconductor device of the first embodiment.

FIG. 6A is a perspective view of the semiconductor device of the first embodiment.

FIG. 6B is a plan view of the semiconductor device of the first embodiment.

FIG. 7A is a diagram showing the leakage current and driving voltage of the semiconductor device of the first embodiment.

FIG. 7B is a diagram showing the leakage current and driving voltage of the semiconductor device of the first embodiment.

FIG. 8 is a plan view of the semiconductor device of the first embodiment.

FIG. 9 is a cross-sectional view of a semiconductor device of a second embodiment.

FIG. 10A is a plan view of the semiconductor device of the second embodiment.

FIG. 10B is a plan view of the semiconductor device of a comparative example.

FIG. 11 shows the electrical characteristics of the semiconductor device of the second embodiment.

FIG. 12A is a cross-sectional view of the semiconductor device of the second embodiment.

FIG. 12B is a cross-sectional view of the semiconductor device of the second embodiment.

FIG. 13 is a diagram showing the electrical characteristics of the semiconductor device of the second embodiment.

FIG. 14A is a diagram showing the electrical characteristics of the semiconductor device of the second embodiment.

FIG. 14B is a diagram showing the electrical characteristics of the semiconductor device of the second embodiment.

### DETAILED DESCRIPTION

Hereinafter, embodiments of the present disclosure will be described in detail with reference to the drawings. In the specification and drawings, the same or corresponding components are denoted by the same reference numerals, and redundant description is omitted. In the drawings, for convenience of explanation, some configurations may be omitted or simplified. Also, at least some of the embodiments may be arbitrarily combined with each other.

In the semiconductor device of the present disclosure, the conductivity type (p-type or n-type) of semiconductor substrates, semiconductor regions, diffusion regions, transistors, etc., may be inverted. Therefore, if one conductivity type of n-type and p-type is designated as the first conductivity type and the other conductivity type as the second conductivity type, the first conductivity type can be p-type and the second conductivity type can be n-type, or the first conductivity type can be n-type and the second conductivity type can be p-type.

The impurity concentration of components included in the semiconductor device of the present disclosure refers to the peak value in the measured region of the component. Also, when comparing the impurity concentrations of two components, the term “approximately the same” does not mean they are perfectly identical. Even if the impurity concentrations of two components differ due to manufacturing variations, if the set values of the impurity concentrations of the two components are the same, the impurity concentrations of the two components are considered to be the same.

### First Embodiment

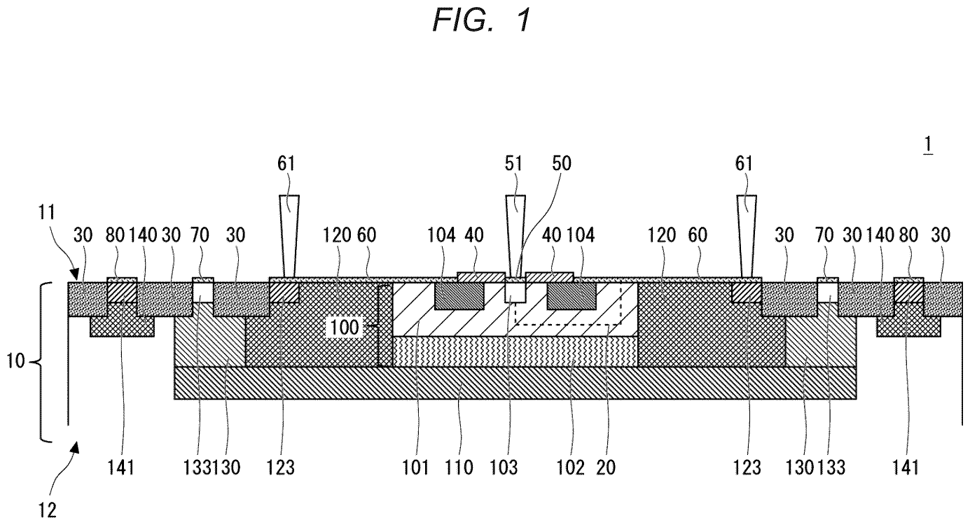

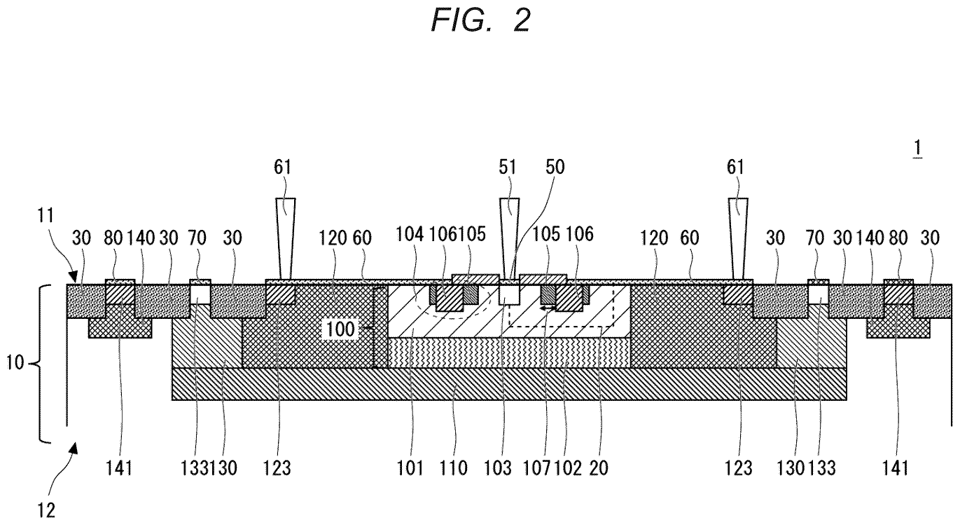

As shown in FIG. 1, a semiconductor device 1 includes a semiconductor substrate 10 having a first conductivity type and a plurality of regions formed in and on the semiconductor substrate 10. FIGS. 2 to 4 are cross-sectional views showing modified examples of the semiconductor device 1, respectively.

Examples of the semiconductor device 1 include a semiconductor chip including a Schottky barrier diode, a semiconductor wafer including a Schottky barrier diode, and packages in which the semiconductor chip or semiconductor wafer are internally mounted.

The semiconductor substrate 10 has an upper surface 11 and a lower surface 12. Hereinafter, unless otherwise specified, components included in the semiconductor device 1 shown in FIG. 1 are formed on/at the upper surface 11 of the semiconductor substrate 10.

A buried region 110 having the second conductivity type opposite the first conductivity type, is formed in the semiconductor substrate 10. The buried region 110 is formed, for example, by introducing impurities indicating the second conductivity type into the semiconductor substrate 10.

A first semiconductor region 100 is formed in the semiconductor substrate 10 and on the buried region 110. The first semiconductor region 100 includes a first semiconductor layer 101 having the second conductivity type and a second semiconductor layer 102 disposed under the first semiconductor layer 101 and having the first conductivity type. The impurity concentration of the first semiconductor region 100 is, for example, lower than the impurity concentration of the semiconductor substrate 10 and equal to or less than the impurity concentration of the buried region 110. Also, the impurity concentrations of the first semiconductor layer 101 and the second semiconductor layer 102 are, for example, approximately the same as each other.

A cathode region 103 having the second conductivity type is formed in the first semiconductor layer 101 of the first semiconductor region 100. The cathode region 103 is formed at the upper surface of the first semiconductor layer 101. The cathode region 103 is electrically connected to a first electrode 51, which is a contact plug formed on the cathode region 103. The impurity concentration of the cathode region 103 is, for example, higher than the impurity concentration of the first semiconductor layer 101.

The first electrode 51 is disposed on the cathode region 103. Between the cathode region 103 and the first electrode 51, a first conductive layer 50 is formed, and the cathode region 103 is connected to the first electrode 51 via the first conductive layer 50.

A first region 104 is formed in the first semiconductor layer 101 of the first semiconductor region 100. The first region 104 is disposed between a region in contact with a second conductive layer 60 of the first semiconductor region 100 and the cathode region 103, in a direction along the upper surface 11 of the semiconductor substrate 10. The first region 104 is formed by introducing impurities of a first conductivity type into the first semiconductor layer 101. The impurity concentration of the first region 104 is, for example, higher than the impurity concentration of the semiconductor region 100 and lower than the impurity concentration of the cathode region 103. Moreover, when the upper surface 11 of the semiconductor substrate 10 is used as a reference surface, the depth of the first region 104 is greater than the depth of the cathode region 103. It should be noted that even when the upper surface of the first semiconductor region 100 is used as a reference surface, the depth of the first region 104 is greater than the depth of the cathode region 103.

A second semiconductor region 120 is disposed in the semiconductor substrate 10 and on the buried region 110 and is formed to surround the first semiconductor region 100 in plan view. The second semiconductor region 120 has a first conductivity type, and the impurity concentration of the second semiconductor region 120 is, for example, approximately the same as the impurity concentration of the first semiconductor region 100.

In the second semiconductor region 120, an anode region 123 having a first conductivity type is formed. The anode region 123 is formed at the upper surface of the second semiconductor region 120. The anode region 123 is electrically connected to a second electrode 61, which is a contact plug formed on the anode region 123. The impurity concentration of the anode region 123 is, for example, higher than the impurity concentration of the second semiconductor region 120.

The second electrode 61 is disposed on the anode region 123. Moreover, in plan view, the second electrode 61 is disposed to overlap the anode region 123. The second conductive layer 60 is formed between the anode region 123 and the second electrode 61, and the anode region 123 is connected to the second electrode 61.

The second conductive layer 60 is formed on the semiconductor substrate to be in contact with the first semiconductor region 100 and the first region 104. Moreover, an insulating layer 40 is formed between the second conductive layer 60 and the first conductive layer 50. The second conductive layer 60 and the first conductive layer 50 are electrically isolated from each other by the insulating layer 40.

A third semiconductor region 130 is disposed in the semiconductor substrate 10 and on the buried region 110 and is formed to surround the first semiconductor region 100 and the second semiconductor region 120 in plan view. The third semiconductor region 130 has a second conductivity type, and the impurity concentration of the third semiconductor region 130 is, for example, approximately the same as the impurity concentrations of the first semiconductor region 100 and the second semiconductor region 120.

In the third semiconductor region 130, a contact region 133, which is a second region having a second conductivity type, is formed. Furthermore, a third conductive layer 70, which is an electrode pad, is formed on the contact region 133 to be in contact with the contact region 133. The impurity concentration of the contact region 133 is, for example, higher than the impurity concentration of the third semiconductor region 130. On the third conductive layer 70, a third electrode (not shown) is formed, and the contact region 133 is connected to the third electrode via the third conductive layer 70.

A fourth semiconductor region 140 is formed in the semiconductor substrate 10 and is formed to surround the first semiconductor region 100, the second semiconductor region 120, and the third semiconductor region 130 in plan view. The fourth semiconductor region 140 has a first conductivity type, and the impurity concentration of the fourth semiconductor region 140 is, for example, approximately the same as the impurity concentrations of the first semiconductor region 100, the second semiconductor region 120, and the third semiconductor region 130.

In the fourth semiconductor region 140, a ground region 143 having a first conductivity type is formed. Furthermore, a fourth conductive layer 80, which is an electrode pad, is formed on the ground region 143 to be in contact with the ground region 143. The impurity concentration of the ground region 143 is, for example, higher than the impurity concentration of the fourth semiconductor region 140.

A buried insulating layer 30 is formed in the semiconductor substrate 10. In plan view, the buried insulating layer 30 is disposed between the second conductive layer 60 and the third conductive layer 70, and between the third conductive layer 70 and the fourth conductive layer 80. The buried insulating layer 30 is formed by forming trenches in the semiconductor substrate 10 for the first conductive layer 50, the second conductive layer 60, the third conductive layer 70, and the fourth conductive layer 80, and then filling the insulating film in the trenches.

In the semiconductor device 1 of the first embodiment, a Schottky barrier is formed between the first semiconductor region 100 and the second conductive layer 60, and the first semiconductor region 100 and the second conductive layer 60 configure a Schottky barrier diode having a current path 20 shown in FIG. 1. Compared to when the first region 104 is not formed, the current path 20 is disposed away from the upper surface 11 due to the first region 104 formed in the first semiconductor layer 101 of the first semiconductor region 100. Therefore, the current path 20 is narrowed by the first region 104.

As a result, it is possible to relax the electric field concentrated at the corners of the second conductive layer 60, which is a Schottky electrode, during reverse bias, and to relax the electric field extending directly under the second conductive layer 60, thereby suppressing tunneling leak current.

Next, a modified example of the semiconductor device 1 of the first embodiment will be described. Note that the explanation may omit repetition for components similar to those in the first embodiment.

FIG. 2 shows a modified example of the first region 104 formed in the first semiconductor layer 101 of the first semiconductor region 100. The first region 104 surrounded by dotted lines in FIG. 2, has a first portion 105 and a second portion 106. Furthermore, in plan view, the first portion 105 is formed to surround the second portion 106.

The first portion 105 is formed by introducing impurities indicating a first conductivity type, similar to the first region 104 in FIG. 1. The impurity concentration of the first portion 105 is, for example, higher than the impurity concentration of the first semiconductor region 100.

The second portion 106 is formed by introducing impurities indicating a first conductivity type, similarly to the first portion 105. The impurity concentration of the second portion 106 is higher than the impurity concentration of the first portion 105, for example. Moreover, when the upper surface 11 of the semiconductor substrate 10 is used as a reference surface, the depth of the second portion 106 is greater than the depth of the cathode region 103. It is also noted that even when the upper surface of the first semiconductor region 100 is used as a reference surface, the depth of the second portion 106 is greater than the depth of the cathode region 103. By such a configuration, the second portion 106 functions as a potential barrier, allowing the current path 20 to be disposed away from the upper surface of the semiconductor substrate 10 compared to when the first region 104 is not formed. Therefore, the current path 20 is narrowed by the second portion 106.

Furthermore, the first portion 105 has an offset region 107 that separates the second portion 106 from the cathode region 103 in a direction along the upper surface 11 of the semiconductor substrate 10. If only the second portion 106 is formed in the first semiconductor layer 101, an electric field may concentrate at the interface between the second portion 106 and the first semiconductor layer 101. Therefore, by forming the first portion 105 having the offset region 107, it is possible to secure a breakdown voltage.

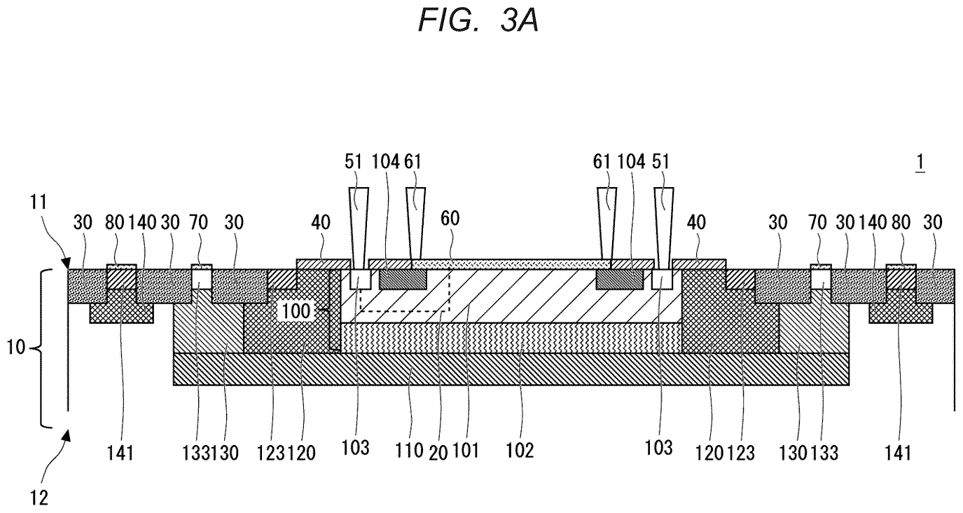

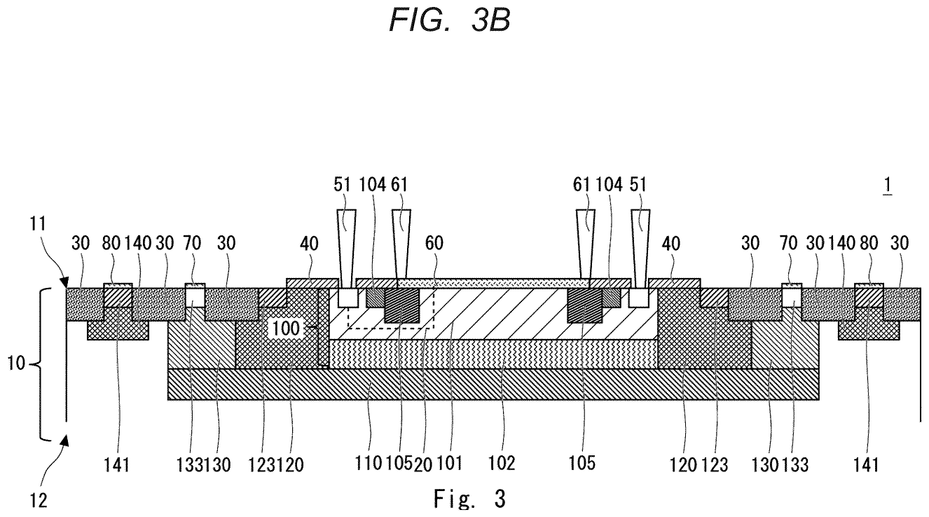

FIG. 3A shows an application example of the semiconductor device 1 shown in FIG. 1, and FIG. 3B shows an application example of the semiconductor device 1 shown in FIG. 2. FIGS. 3A and 3B show a layout where the Schottky electrode, which is the second conductive layer 60, is disposed inside relative to the cathode electrode, which is the first electrode 51, compared to FIGS. 1 and 2. Even in such a configuration, it is possible to relax the electric field between the second conductive layer 60 and the first electrode 51 during reverse bias. Therefore, the semiconductor device 1 of the first embodiment is not limited by the layout of the Schottky electrode and the cathode electrode. Moreover, the first conductive layer 50 may be formed between the cathode region 103 and the first electrode 51.

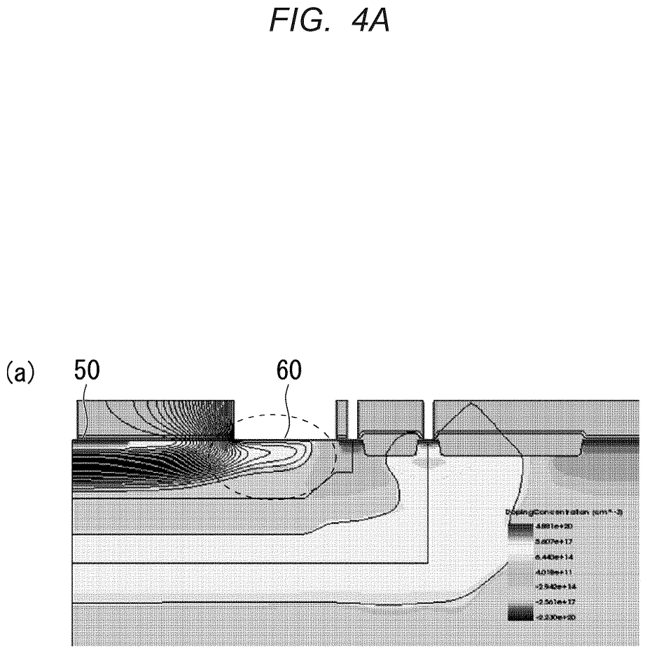

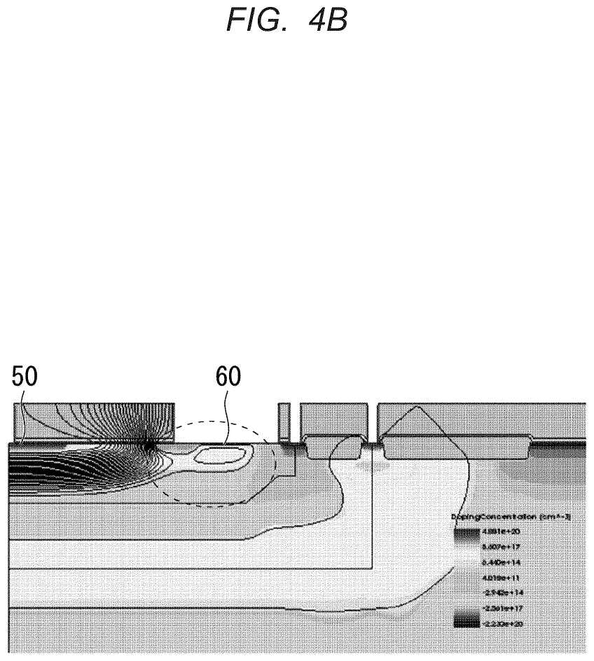

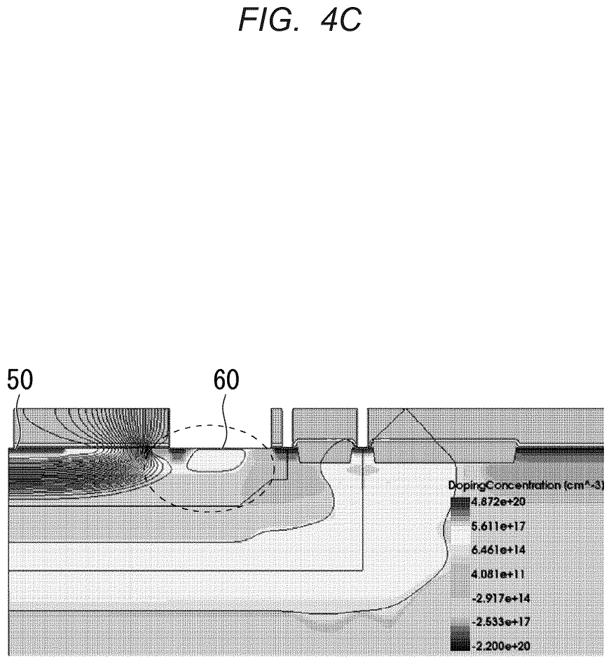

FIGS. 4A, 4B, and 4C are diagrams showing simulation results of the electric field strength distribution in the semiconductor device during reverse bias application. FIG. 4A is a diagram showing the potential distribution in the semiconductor device 1 without the first region 104 as a comparative example. FIG. 4B shows the potential distribution of the semiconductor device 1 shown in FIG. 1, and FIG. 4C shows the potential distribution of the semiconductor device 1 shown in FIG. 2.

In the comparative example, as shown by the dotted lines in FIG. 4A, it can be seen that an electric field concentrating at the corner of the Schottky electrode, which is the second conductive layer 60, and an electric field extending directly under the second conductive layer 60 are observed. On the other hand, in the semiconductor device 1 of the first embodiment, as shown by the dotted lines in FIG. 4B and FIG. 4C, it can be seen that the electric field is relaxed.

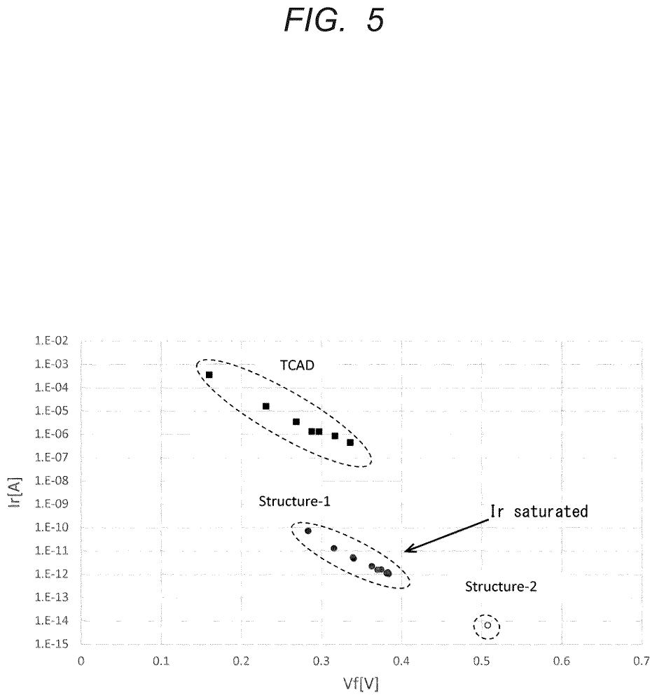

FIG. 5 is a diagram showing the correlation between leak current and driving voltage. FIG. 5 shows the simulation results (TCAD) of the semiconductor device of the comparative example, the simulation results (Structure-1) of the semiconductor device of FIG. 1, and the simulation results (Structure-2) of the semiconductor device of FIG. 2. The horizontal axis of FIG. 5 indicates the driving voltage Vf, and the vertical axis of FIG. 5 indicates the leak current Ir.

It can be seen that the leak current Ir is suppressed in the semiconductor devices of FIGS. 1 and 2 compared to the semiconductor device of the comparative example. On the other hand, in the semiconductor device of FIG. 1, it is found that the decreasing trend of the leak current Ir saturates around a driving voltage Vf of 0.4 V. Furthermore, in the semiconductor device of FIG. 2, while the leak current Ir is suppressed, an increase in the driving voltage Vf is observed.

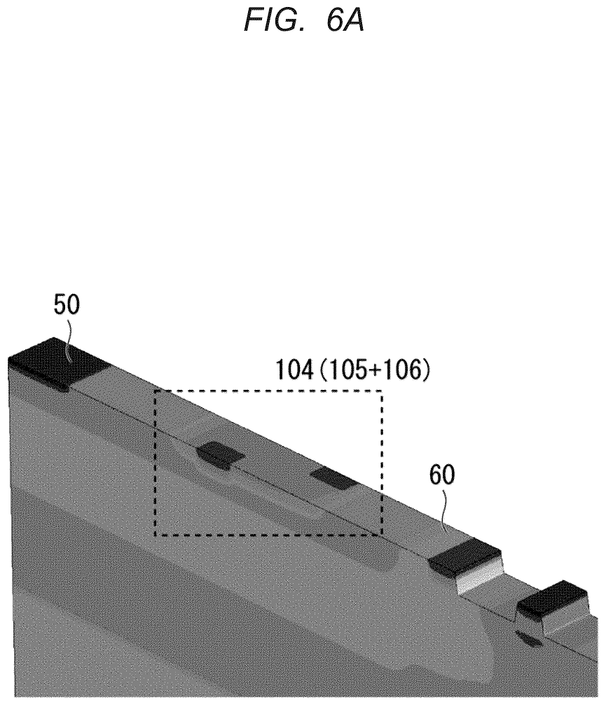

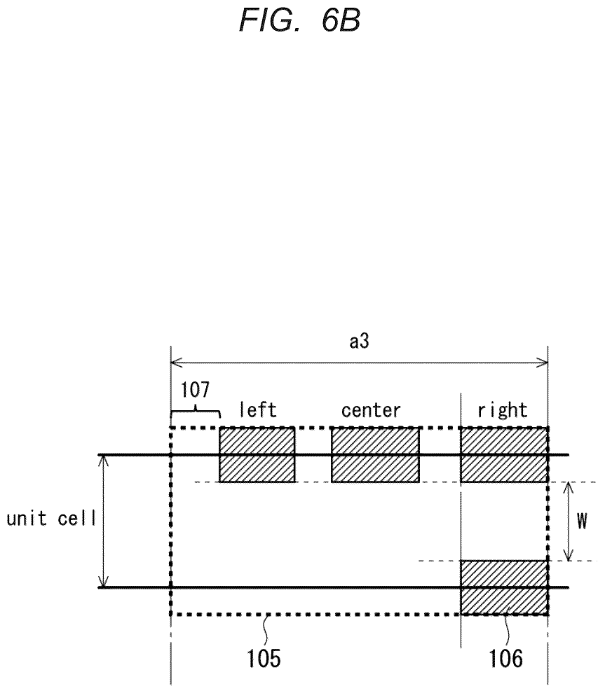

In order to improve the driving voltage Vf of the semiconductor device 1 in the configuration of FIG. 2, FIG. 6 shows an example of modifying the arrangement of the second portion 106 in the first region 104. FIG. 6A shows a perspective view of a modified example of the semiconductor device 1 of the first embodiment, and FIG. 6B shows a plan view of a modified example of the semiconductor device 1 of the first embodiment. In the first portion 105 indicated by the dotted line in FIG. 6B, while fixing the offset region 107, the arrangement and size of the second portion 106 were changed, and a simulation was performed.

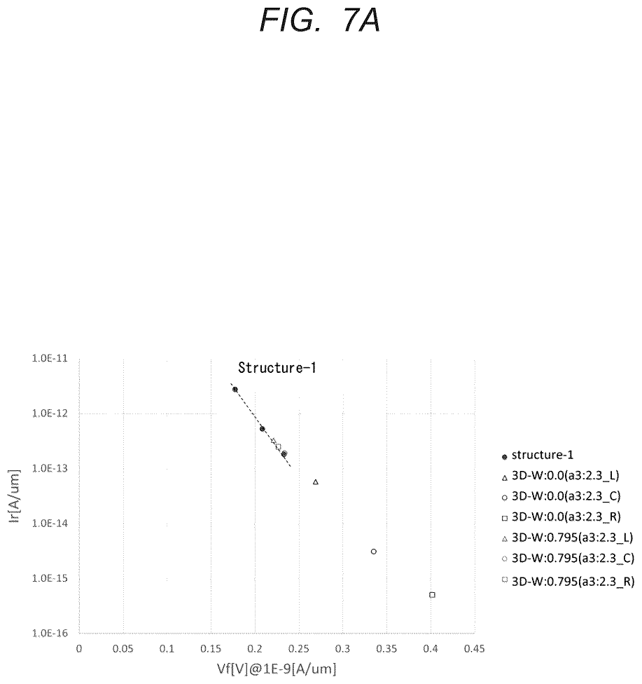

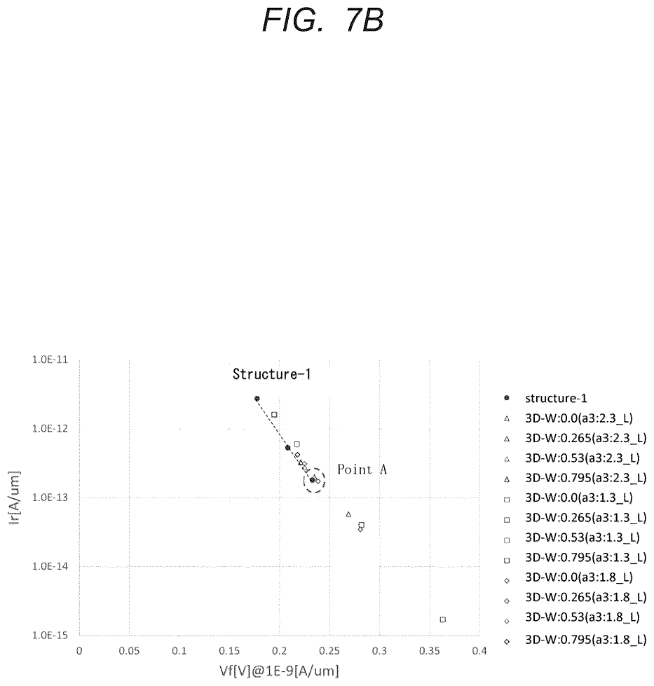

FIGS. 7A and 7B show simulation results of the correlation between the leakage current and the driving voltage of the semiconductor device 1 shown in FIGS. 6A and 6B. Note that the plots in FIGS. 7A and 7B are normalized at a specified current value for the simulation results of the second portion 106 in a houndstooth check pattern, for comparison with the simulation results of the semiconductor device 1 shown in FIG. 1.

FIG. 7A shows the position dependency when the lower part of the second portion 106 in FIG. 6B is fixed to the right position, and the upper part of the second portion 106 is placed in the left, center, and right positions. From FIG. 7A, it was confirmed that an increase in Vf is observed with the suppression of Ir when the width W of the first portion 105 is 0 μm. On the other hand, when the width W of the first portion 105 is 0.795 μm, it was found that the position dependency of the second portion 106 is relaxed due to the wider current path.

FIG. 7B shows the dependency of the width of the region 105 including the second portion 106 in a houndstooth check pattern when the upper part of the second portion 106 in FIG. 6B is placed in the left position and the width a3 of the first region 104. At Point A in FIG. 7B, the a3 of the semiconductor device in the configuration of FIG. 1 (structure-1) is 3.3 μm, and the a3 of the semiconductor device in the configuration of FIG. 6 is 1.8 μm. Therefore, the configuration of FIG. 6 can reduce the leakage current Ir with a smaller size of the Schottky barrier diode compared to the configuration of FIG. 2. A significant advantage of the configuration of FIG. 6 is that it allows control of the driving voltage Vf and the leakage current Ir without increasing the size of the Schottky barrier diode, via the width W of the first portion 105.

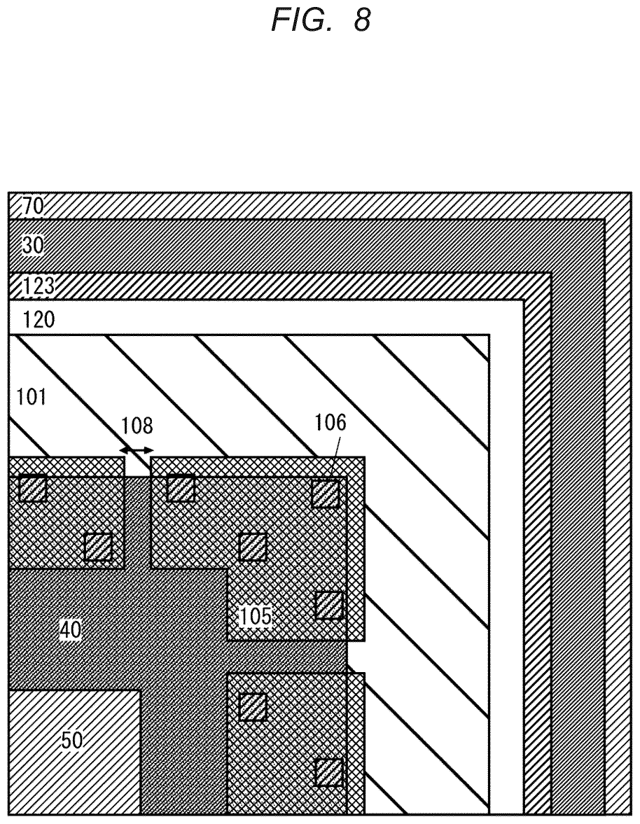

FIG. 8 is a plan view of the semiconductor device 1 of FIG. 6. The shape of the second portion 106 in plan view is strip-shape or dot-shape. When the shape of the second portion 106 is dotted, the shape of the second portion 106 may be square-shape, circular-shape, elliptical-shape, triangular-shape, rectangular-shape, trapezoidal-shape, or any polygonal-shape with five or more sides. Furthermore, when the shape of the second portion 106 is dot-shape, the plurality of second portions 106 may form a houndstooth check pattern or linear pattern. Also, the shape of the first portion 105 in plan view may have a stripe-shape or intermittent pattern, or as shown in FIG. 8, may have a shape with a gap 108 between two adjacent first portions 105.

### Second Embodiment

In the second embodiment, a modified example of the semiconductor device 1 of the first embodiment is described. Note that the explanation may be omitted for components that are similar to those in the configuration example of the first embodiment.

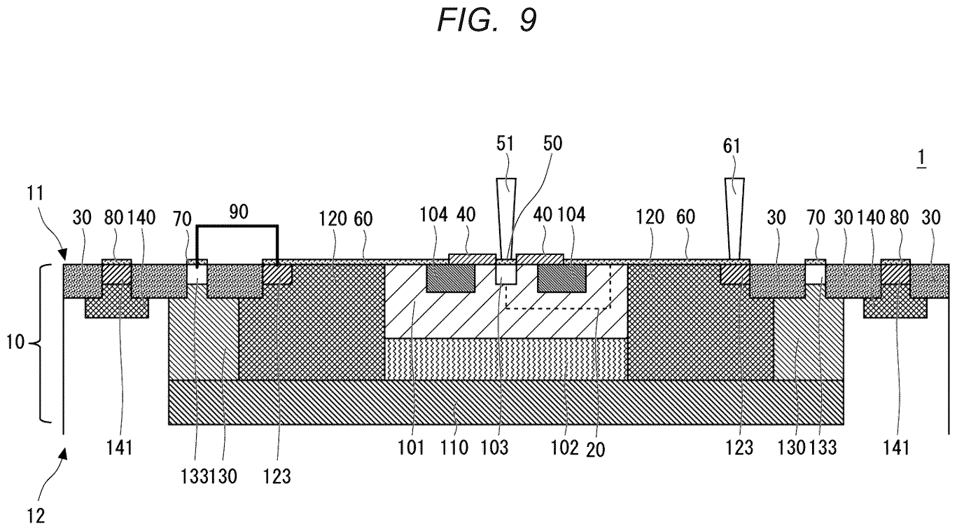

The semiconductor device 1 shown in FIG. 9 has the anode region 123 formed in the second semiconductor region 120, the contact region 133 formed in the third semiconductor region 130, and a wiring 90 formed on the semiconductor substrate 10. Moreover, the semiconductor device 1 has the wiring 90 formed on the semiconductor substrate 10, connecting the anode region 123 and the contact region 133. Thus, the second conductive layer 60 and the third conductive layer 70 are electrically connected to each other. Similarly to the first embodiment, a third electrode (not shown) is formed on the third conductive layer 70, and the contact region 133 is connected to the third electrode via the third conductive layer 70. Therefore, the second electrode 61 is connected to the third electrode via the wiring 90. This allows the operation of a parasitic bipolar transistor to be suppressed, preventing leakage current from flowing in the semiconductor substrate.

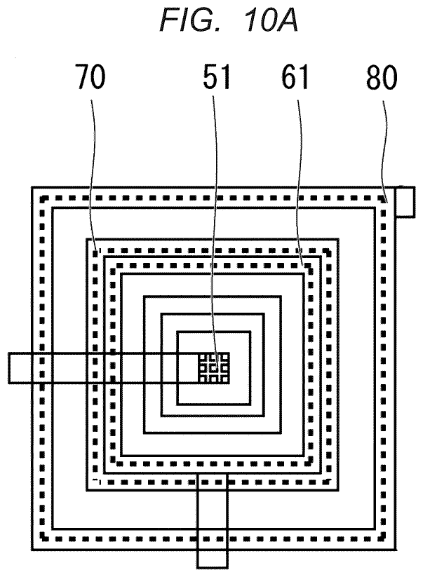

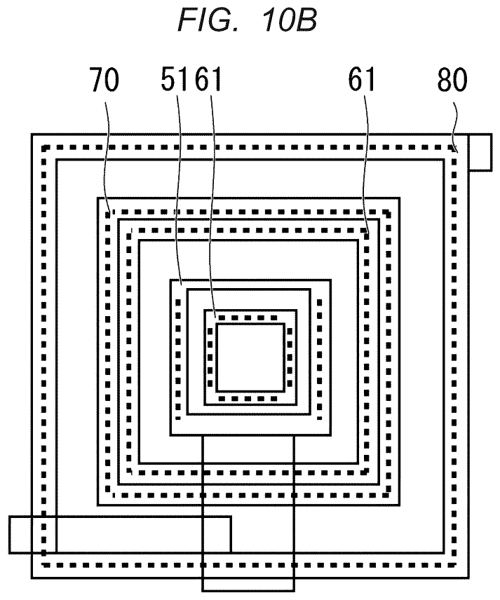

In the semiconductor device of the first embodiment, it is possible to suppress the leakage current without being limited by the layout of the Schottky electrode and the cathode electrode. On the other hand, in the semiconductor device 1 of the second embodiment, it is preferable from the viewpoint of reducing the region of the Schottky barrier diode that the first electrode 51 is disposed in the second electrode 61, which is the anode electrode. FIG. 10A shows a plan view of the semiconductor device 1 of the second embodiment, and FIG. 10B shows a plan view of a semiconductor device as a comparative example in which the second electrode 61 is disposed inside the first electrode 51. By positioning the cathode electrode, which is the first electrode 51, inside the anode electrode, which is the second electrode 61, it is possible to reduce the region of the Schottky barrier diode. Moreover, it becomes possible to improve the degree of freedom in layout by reducing the number of wirings.

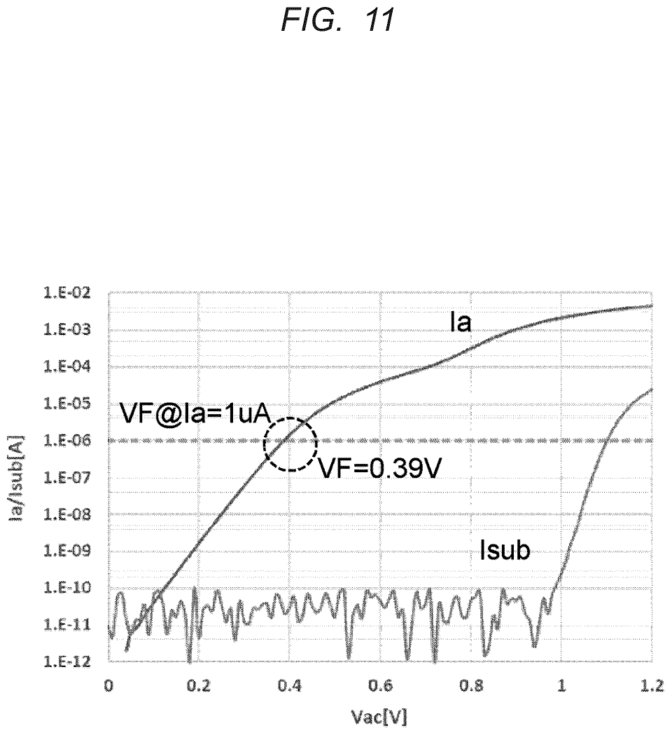

FIG. 11 shows the forward waveform of the electrical characteristics of the Schottky barrier diode of the semiconductor device 1 of the present embodiment. The driving voltage Vf at an on-current Ia of 1 μA is 0.39 V, indicating good electrical characteristics.

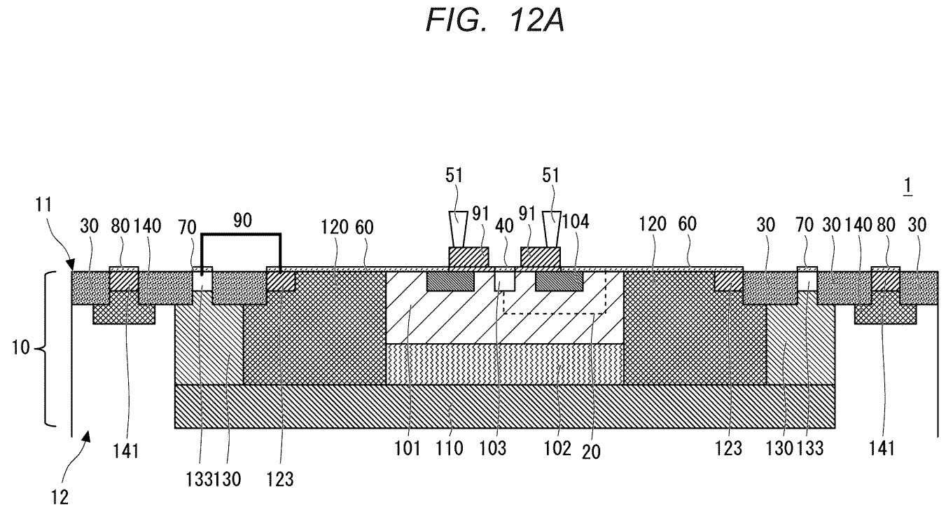

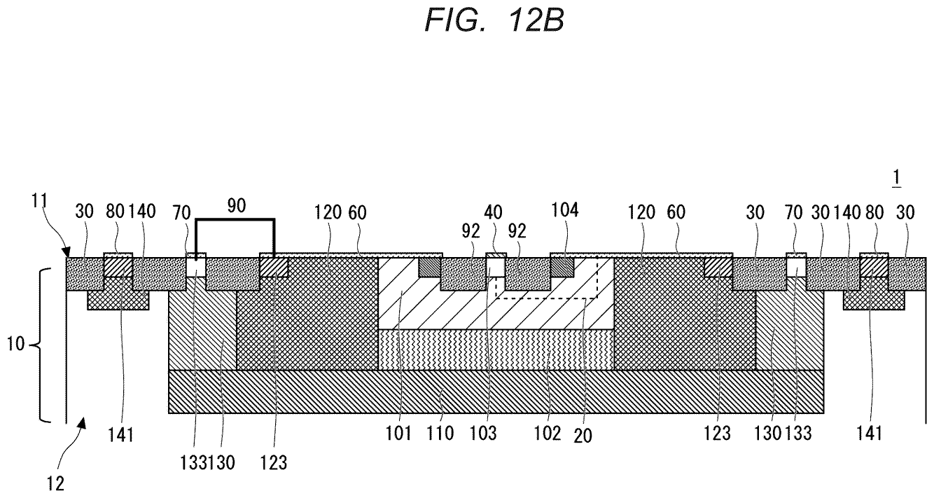

FIGS. 12A and 12B show modified examples of the semiconductor device 1 according to the second embodiment. FIG. 12A shows a configuration in which a metal silicide layer 91 is formed on the first region 104. The semiconductor substrate 10 may have a Laterally Diffused Metal Oxide Semiconductor Field Effect Transistor (LDMOSFET) formed thereon, in addition to a Schottky barrier diode. Since the metal silicide layer 91 can be formed using a mask for introducing the drift layer of the LDMOSFET around the Schottky barrier diode, the metal silicide layer 91 can be formed without increasing the number of masks.

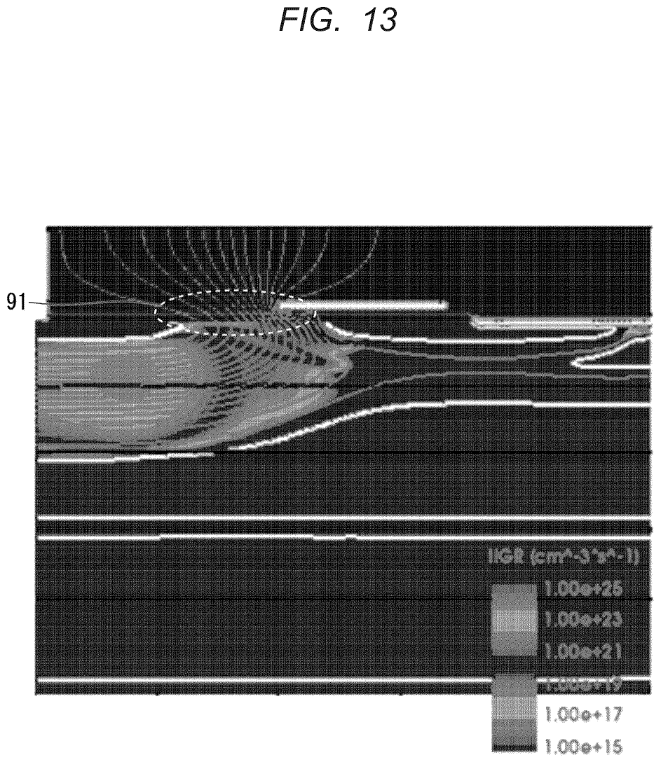

FIG. 13 is a diagram showing the simulation results of the electric field strength distribution in the semiconductor device when a reverse bias is applied. By positioning the end of the metal silicide layer 91 between the first region 104 and the cathode region 103 in plan view, it is possible to relax the electric field, thereby improving the breakdown voltage of the Schottky barrier diode.

FIG. 12B shows a configuration in which a buried insulating layer 92, which is an insulating region that penetrates through the first region 104 and surrounds the first region 104, is formed. When the upper surface 11 of the semiconductor substrate 10 is used as a reference surface, it is preferable that the depth of the buried insulating layer 92 is greater than the depth of the first region 104. By forming the buried insulating layer 92, it is possible to narrow the current path 20. Furthermore, the buried insulating layer 92 can be formed in the same process as the buried insulating layer 30.

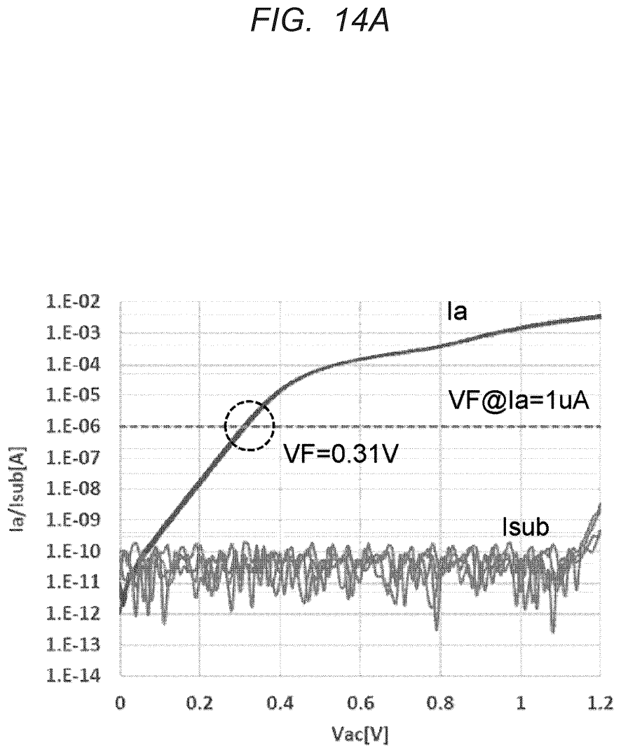

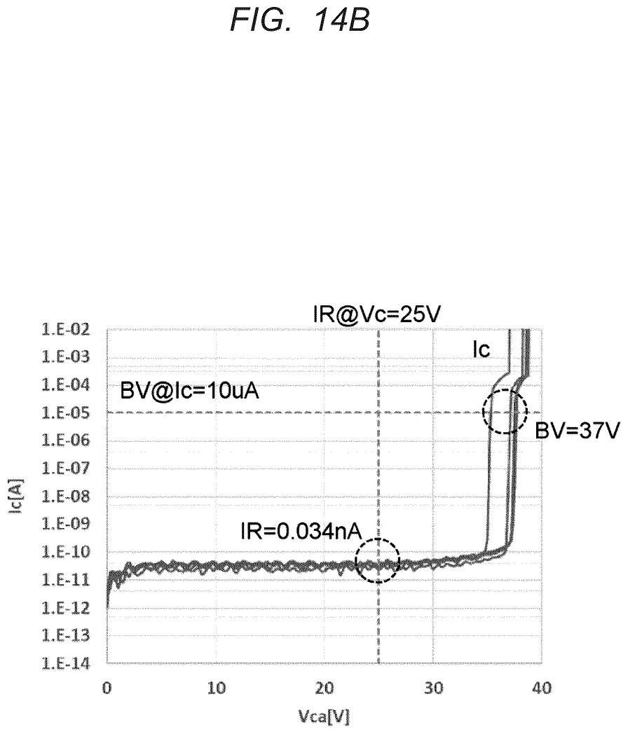

FIG. 14A shows the forward waveform of the electrical characteristics of the Schottky barrier diode of the semiconductor device 1 of the second embodiment. It was found that the device has good electrical characteristics with a driving voltage Vf of 0.31 V when the on-current Ia is 1 μA.

FIG. 14B shows the reverse waveform of the electrical characteristics of the Schottky barrier diode of the semiconductor device 1 of the second embodiment. When 25 V was applied to the Schottky barrier diode, the leakage current Ir was lower than the specified value shown by the dotted line, and the breakdown voltage BV was 37 V. Therefore, it was found that the Schottky barrier diode of the semiconductor device 1 of the second embodiment has sufficient resistance.

Thus, by incorporating the configuration of the second embodiment, it is possible to provide a semiconductor device that can further suppress leakage current.

As described above, the invention made by the inventors has been concretely explained based on the embodiments, but it goes without saying that the present disclosure is not limited to the embodiments already mentioned and various changes can be made without departing from the gist thereof.

What is claimed is:

1. semiconductor device comprising:
a semiconductor substrate having an upper surface;
a first semiconductor region formed in the semiconductor substrate;
a second semiconductor region formed in the semiconductor substrate and surrounding the first semiconductor region in plan view;
a first conductive layer formed on the first semiconductor region;
a first electrode formed on the first conductive layer;
a cathode region formed in the first semiconductor region and connected to the first electrode via the first conductive layer;
a second conductive layer formed on the first semiconductor region and being in contact with the first semiconductor region;
a second electrode formed on the second conductive layer; and
a first region formed in the first semiconductor region and being in contact with a lower surface of the second conductive layer, the first region being disposed between a region in contact with the second conductive layer of the first semiconductor region and the cathode region in a direction along the upper surface of the semiconductor substrate,
wherein, when the upper surface of the semiconductor substrate is used as a reference surface, a depth of the first region is greater than a depth of the cathode region,
wherein the semiconductor substrate, the second semiconductor region, and the first region each have a first conductivity type, and
wherein the first semiconductor region and the cathode region each have a second conductivity type opposite the first conductivity type.

2. The semiconductor device according to claim 1,
wherein the first region comprises a first portion and a second portion,
wherein, when the upper surface of the semiconductor substrate is used as a reference surface, a depth of the second portion is greater than the depth of the cathode region and the depth of the first portion,
wherein the first portion comprises an offset region separating the second portion from the cathode region in the direction along the upper surface of the semiconductor substrate,
wherein the offset region is disposed between the cathode region and the second portion, and
wherein an impurity concentration of the second portion is higher than an impurity concentration of the first portion.

3. The semiconductor device according to claim 1,
wherein the first semiconductor region and the second conductive layer configure a Schottky barrier diode.

4. The semiconductor device according to claim 3,
wherein the first semiconductor region comprises:
a first semiconductor layer having the second conductivity type; and
a second semiconductor layer disposed under the first semiconductor layer and having the first conductivity type, and
wherein a current path of the Schottky barrier diode is formed in the first semiconductor layer and narrowed by the first region.

5. The semiconductor device according to claim 2,
wherein a shape of the second portion in plan view is stripe-shape or dot-shape, and
wherein, when the shape of the second portion in plan view is dot-shape, a shape of the first portion is one of circular-shape, elliptical-shape, triangular-shape, square-shape, rectangular-shape, trapezoidal-shape, or polygonal-shape with five or more sides.

6. The semiconductor device according to claim 5,
wherein, when the shape of the second portion in plan view is dot-shape, the second portion comprises a plurality of second portions and the plurality of second portions form a houndstooth check pattern or a linear pattern.

7. The semiconductor device according to claim 5,
wherein the shape of the first portion in plan view is stripe-shape or has an intermittent pattern.

8. The semiconductor device according to claim 1, further comprising:
a buried region formed in the semiconductor substrate, the buried region being disposed under the first semiconductor region and the second semiconductor region, and the buried region having the second conductivity type; and
a third semiconductor region formed in the semiconductor substrate, the third semiconductor region surrounding the first semiconductor region and the second semiconductor region in plan view, and the third semiconductor region having the second conductivity type,
wherein the third semiconductor region is connected to the buried region.

9. The semiconductor device according to claim 8, further comprising:
a third conductive layer formed on the third semiconductor region;
a third electrode formed on the third conductive layer; and
a second region formed in the third semiconductor region and connected to the third electrode via the third conductive layer,
wherein an impurity concentration of the second region is higher than an impurity concentration of the third semiconductor region, and
wherein the second electrode and the third electrode are connected to each other via a wiring.

10. The semiconductor device according to claim 9, further comprising:
a metal silicide layer between the first electrode and the first conductive layer.

11. The semiconductor device according to claim 9, further comprising:
an insulating region disposed to surround the first region in plan view,
wherein, when the upper surface of the semiconductor substrate is used as a reference surface, a depth of the insulating region is greater than the depth of the first region.

12. The semiconductor device according to claim 1, further comprising:
an anode region formed in the second semiconductor region and connected to the second electrode via the second conductive layer; and
an insulating layer formed between the first conductive layer and the second conductive layer,
wherein the second conductive layer is formed on the first semiconductor region and on the second semiconductor region,
wherein the first region is formed to surround the cathode region and is disposed under the insulating layer and under the second conductive layer, and
wherein in plan view, the second electrode is disposed to overlap the anode region.

13. The semiconductor device according to claim 1, further comprising:
an anode region formed in the second semiconductor region and connected to the second electrode via the second conductive layer; and
an insulating layer formed between the first electrode and the second conductive layer,
wherein the cathode region is formed to surround the first region,
wherein the first region is disposed under the insulating layer and under the second conductive layer, and
wherein in plan view, the second electrode is disposed to overlap the anode region.

14. A semiconductor device comprising:
a semiconductor substrate having an upper surface;
a first semiconductor region formed in the semiconductor substrate;
a second semiconductor region formed in the semiconductor substrate and surrounding the first semiconductor region in plan view;
a first conductive layer formed on the first semiconductor region;
a first electrode formed on the first conductive layer;
a cathode region formed in the first semiconductor region and connected to the first electrode via the first conductive layer;
a second conductive layer formed on the first semiconductor region and on the second semiconductor region, the second conductive layer being in contact with the first semiconductor region;
a second electrode formed on the second conductive layer;
an anode region formed in the second semiconductor region and connected to the second electrode via the second conductive layer;
a first region formed in the first semiconductor region and disposed between the cathode region and the second semiconductor region in a direction along the upper surface of the semiconductor substrate, the first region being in contact with a lower surface of the second conductive layer;
a buried region formed in the semiconductor substrate and disposed under the first semiconductor region and under the second semiconductor region;
a third semiconductor region formed in the semiconductor substrate and surrounding the first semiconductor region and the second semiconductor region in plan view;
a third conductive layer formed on the third semiconductor region;
a third electrode formed on the third conductive layer; and
a second region formed in the third semiconductor region and connected to the third electrode via the third conductive layer,
wherein, when the upper surface of the semiconductor substrate is used as a reference surface, a depth of the first region is greater than a depth of the cathode region,
wherein the semiconductor substrate, the second semiconductor region, the anode region, and the first region each have a first conductivity type,
wherein the first semiconductor region, the cathode region, the buried region, and the third semiconductor region each have a second conductivity type opposite the first conductivity type,
wherein the third semiconductor region is connected to the buried region,
wherein an impurity concentration of the second region is higher than an impurity concentration of the third semiconductor region, and
wherein the second electrode and the third electrode are connected to each other via a wiring.

15. The semiconductor device according to claim 14,
wherein the first semiconductor region and the second conductive layer configure a Schottky barrier diode.

16. The semiconductor device according to claim 15,
wherein the first semiconductor region comprises:
a first semiconductor layer having the second conductivity type; and
a second semiconductor layer disposed under the first semiconductor layer and having the first conductivity type, and
wherein a current path of the Schottky barrier diode is formed in the first semiconductor layer and narrowed by the first region.

17. The semiconductor device according to claim 14, further comprising:
a metal silicide layer between the first electrode and the first conductive layer.

18. The semiconductor device according to claim 14, further comprising:
an insulating region disposed to surround the first region in plan view,
wherein, when the upper surface of the semiconductor substrate is used as a reference surface, a depth of the insulating region is greater than the depth of the first region.
